(19) United States
(12) Patent Application Publication
(10) Pub. No.: US 2002/0167429 A1
(43) Pub. Date: Nov. 14, 2002

(54) Lossless data compression method for uniform entropy data

(76) Inventor: Dae-Soon Kim, Seoul (KR)

Correspondence Address: HARNESS, DICKEY & PIERCE, P.L.C., P.O. BOX 828, BLOOMFIELD HILLS, MI, 48303, US

(21) Appl. No.: 10/100,365

(22) Filed: Mar. 18, 2002

(30) Foreign Application Priority Data
Mar. 20, 2001 (KR) 2001-14309

(51) Int. Cl. H03M 7/00; G06K 9/36

(52) U.S. Cl. 341/106

(57) ABSTRACT

A new method for compressing uniform entropy data, i.e. data streams of uniform probability distribution for binary code combination in the data stream, such files as MPEG, JPEG, ZIP, ARJ, etc. is disclosed. Contrary to the conventional compression algorithm which uses look-up table dictionary, the new lossless compression method eliminates the dictionary redundancy for temporal data stream and modulates incoming data stream by slicing unit module to have orthogonal correlation characteristics. According to the present invention, the method including the step of converting the uniform entropy property data stream at temporal period into non-uniform entropy property using correlation of continuous binary code combination and random occurrence thereof in the incoming data stream, thereby compressing the uniform entropy data in a lossless way.

### BACKGROUND OF THE INVENTION

1. Field of the Invention

The present invention relates generally to data compression and decompression, and more particularly to a lossless data compression method which operates effectively upon uniform entropy data stream.

2. Description of the Related Art

Data compression methods can be classified into two major families of lossy compression and lossless compression. Lossy compression is an encoding method which removes non-recognizable data ingredients among the binary data of audio-visual information (e.g., movies, video, music) to compress digital data. Currently available lossy compression format includes MPEG, JPEG, etc. for image data, and MP3 and AC3, etc. for audio data.

Lossless compression is mostly used in document files having non-uniform entropy data information. The non-uniform entropy data may refer to a data stream in which its unit character has different occurrence frequency. Lempel-Ziv, Huffman or Arithmetic coding methods are the types of lossless compression algorithms. Currently, lossless compression has developed as commercial software such as WinZip, ARC, and PKZIP, etc., and has been widely used in personal computers. However, lossless compression, which only works with non-uniform entropy data, is not applicable to compress uniform entropy data such as MPEG, JPEG, and MP3 files.

Most of current digital communications and its dependent tools use the audio-visual information compressed by MPEG format which is featured as the lossy compression method. Specifically, in case of digital broadcasting media, all satellite, terrestrial, and cable TV use MPEG format. DVD, VCD and MP3 players also use the lossy compression data. In comparison, the lossless compression method has not been implemented into hardware due to its fundamental limit; uniform entropy data could not be compressed by currently available lossless compression algorithm, resulting in limited application on software compression utility used in personal computers.

Furthermore, lossless compression algorithm cannot be applied to the data inputted to the main memory of personal computers, hard disk drives (HDD), floppy disk drives (FDD), CD-RW and the like because its input data stream may be mixed with uniform entropy data such as MPEG and non-uniform entropy data such as document files. If these data are compressed by conventional lossless compression method, there will be a possibility of increase in data length or information content.

For the purpose of illustration, a typical lossless compression method will be described with reference to Fig. la and lb. Recently available lossless data compression methods are Huffman coding, Arithmetic coding, Dictionary coding, and Lempel-Ziv. As a model, Huffman coding algorithm is used herein to describe the lossless compression method.

For example, let's suppose a data stream “S” that is composed of 16 alphabet characters.

S={a, b, c, a, d, b, a, c, e, a, b, a, c, a, b, a}

S has five characters “a, b, c, d, e” each having different occurrence frequency. Probability for each character can be shown like this:

P(a)=7/16, P(b)=4/16, P(c)=3/16, P(d)=1/16, P(e)=1/16

As above, when composition code of data stream is composed of different occurrence frequency, codeword allocation for each character could be accomplished and compression could be realized with Huffman coding algorithm.

The binary Huffman-tree for the data stream S is shown in FIG. 1a.

Also, by using the Huffman tree of FIG. 1a, the allocated codeword for the data stream S is shown in Table 1.

TABLE 1

| Letter | Probability | Codeword |
|---|---|---|
| a | 7/16 (0.4375) | 1 |
| b | 4/16 (0.25) | 01 |
| c | 3/16 (0.1875) | 000 |
| d | 1/16 (0.0625) | 0010 |
| e | 1/16 (0.0625) | 0011 |

If it is supposed that average bit size per unit character (symbol) of data stream S is “ι” with reference to the bit size of codeword shown in Table 1,

ι=0.4375×1+0.25×2+0.1875×3+0.0625×4+0.0625×4=2 bits/symbol.

Consequently, 2 bits binary code per symbol is required. If Huffman tree is not used, 3 bits per symbol are required for five symbols, and the length of the data stream S would be “3×16=48 bits.” Since 2 bits per symbol is required in case of being compressed by the Huffman tree, the length of the data stream S would be “2×16=32 bits.” Thus, it provides for about 35% compression effect in the data stream.

As described above, the data stream S having non-uniform entropy characteristics can be compressed by using the lossless compression method such as Huffman coding.

The following expression is the case that the data stream has the property of uniform entropy, in other words, occurrence probability for each symbol in the data stream is uniform. If it is supposed that data stream “S′” has uniform entropy property with 16 alphabet characters.

S′={a, d, c, b, d, a, b, c, a, c, d, b, c, d, b, a}

S′ has four characters “a, b, c, d” each having the same occurrence frequency, in other words, the occurrence probability for each character has the flat probability distribution like below:

P(a)=0.25, P(b)=0.25, P(c)=0.25, P(d)=0.25

Referring to FIG. 1b, there is shown Huffman-tree for the data stream S′.

Also, following Table 2 shows when the codeword is allocated to each character of data stream S′ by using Huffman tree.

TABLE 2

| Letter | Probability | Codeword |
|---|---|---|
| a | 0.25 | 1 |
| b | 0.25 | 01 |
| c | 0.25 | 000 |
| d | 0.25 | 001 |

If the average bit size per symbol of data stream S′ is supposed to ι′,

ι=0.25×1+0.25×2+0.25×3+0.25×3=2.25 bits/symbol.

In this case, the binary code of 2.25 bits per unit symbol is required. Without using the Huffman encoding, two bits per symbol are required for four symbols, and the length of data stream S′ would be “2×16=32 bits.” Since 2.25 bits per symbol are required in case of being compressed by Huffman tree, the length of data stream S′ would be “2.25×16=36 bits” which results in increased size of data stream conversely.

As apparent from the above, when the conventional lossless compression method such as Huffman coding is applied to the data stream having the property of such uniform entropy, an increase in amount of data will occur.

Thus, a need exists to provide for an improved and new lossless compression method which effectively operates upon the uniform entropy data stream.

### SUMMARY OF THE INVENTION

It is an object of the present invention to provide a new compression method which can compress uniform entropy data in lossless way.

This invention provides a new method which enables compression of uniform entropy data, i.e. data streams of uniform probability distribution for binary code combination in the data stream, such files as MPEG, JPEG, ZIP, ARJ, etc. which cannot be compressed by the conventional compression method.

The present invention is based on the recognition that the conventional compression algorithm, which uses look-up table dictionary, has difficulties in compressing temporal period of the data stream due to over-sized redundancy flag generated from the look-up table composition. New lossless compression scheme eliminates the dictionary redundancy for temporal data stream and modulates incoming data stream by slicing unit module to have orthogonal correlation characteristics.

According to the present invention, there is provided a method for compressing data stream of uniform entropy data in which incoming unit character has the same occurrence frequency, the method including the step of converting the uniform entropy property of data stream at temporal period into non-uniform entropy property using correlation of continuous binary code combination and random occurrence thereof in the incoming data stream, thereby compressing the uniform entropy data in a lossless way.

According to a preferred embodiment of the present invention, the method for compressing data stream of uniform entropy data by modulating incoming data stream by slicing unit symbol thereof to have orthogonal correlation characteristics comprising the steps of:

inputting a first symbol value X₁ of the incoming data stream X to a first symbol C₁ of the output data stream C and moving the symbol Aᵢ of a status register having the same value as X₁ to the position Aₙ₊₁ thereof;

searching the symbol value of the status register having the same value as that of the second input symbol X₂ and storing the value of a base register corresponding to the obtained symbol value to C₂ of the data stream C;

performing repetitively the step of searching and storing the symbol value by Xₘ for each symbol of the input data stream X, and then storing obtained symbol value to the data stream C; and

compressing the output data stream C by using conventional compression algorithms;

wherein the status register and the base register both have n symbols having different value each other and values of the two registers are the same before initiation of the encoding operation; and wherein the value of the status register is changed by the contents of input data stream X, but the value of the base register remains unchanged.

Further, according to the preferred embodiment of the present invention, there is provided a method for decompressing the data stream compressed according to the compression method of the invention by using the status register and the base register, the method comprising the steps of: extracting data stream C from the compressed data stream with the same method used in the compression step; inputting the first symbol value C₁ of the data stream C to the first symbol X₁ of data stream X, and moving the symbol Aᵢ of status register having the same value as C₁ to the position Aₙ₊₁ of the status register; searching the symbol value of the base register that has the same value as the second input symbol C₂ of the data stream C, and storing the value of the status register corresponding to the symbol value onto X₂; and performing repetitively the above step 2 operation by Cₘ for each symbol of input data stream C and storing them to the data stream X.

The status register and the base register are initialized to the same value as those used in the compression process.

In case this method is adopted, it will increase the storage capacity more than 30% of memory devices such as SRAM, DRAM, Flash ROM as well as recording medium such as HDD, FDD, DVD, and CD-RW. Also, bandwidths of transmission channel in Digital TV, IMT-2000 can be cut off below 70%. For instance, DVD-R storage device of 9.4 GBytes can store 13 GBytes data and TV broadcasting channel of 6 MHz bandwidth digital terrestrial can be reduced near 4 MHz.

### BRIEF DESCRIPTION OF THE DRAWINGS

The foregoing and other objects, features, and advantages of the invention will be apparent from the following, more particular, description of the preferred embodiments of the invention, as illustrated in the accompanying drawings in which,

FIG. 1a illustrates binary Huffman-tree for an exemplary data stream having non-uniform entropy property;

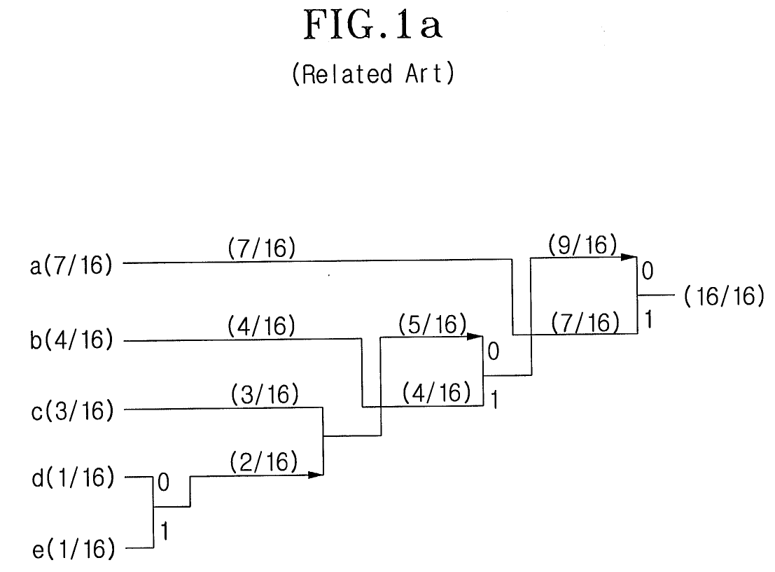

FIG. 1b illustrates the binary Huffman-tree for uniform entropy data stream;

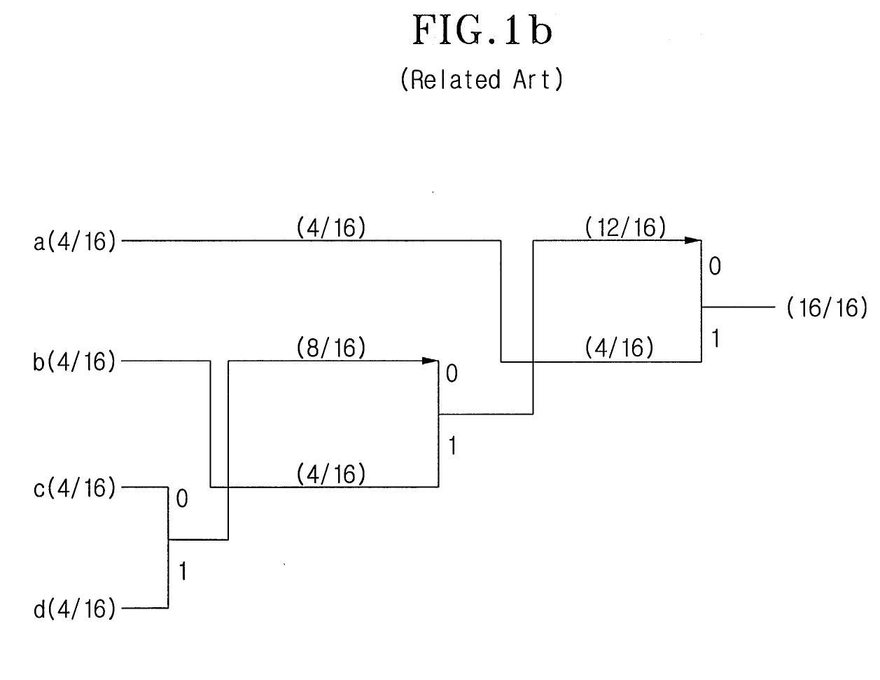

FIG. 2 is simplified block diagram of a compressor for adopting the lossless compression method of the present invention; and

FIG. 3 is simplified block diagram of a decompressor for use in the present invention.

### DETAILED DESCRIPTION OF THE INVENTION

The lossless data compression method of the present invention is capable of compressing uniform entropy data stream at temporal period by converting the property of uniform entropy into that of non-uniform entropy using correlation of continuous binary combination and tendency of random occurrence in the data stream. The present invention also provides a decompression method that restores the compressed data to the original state.

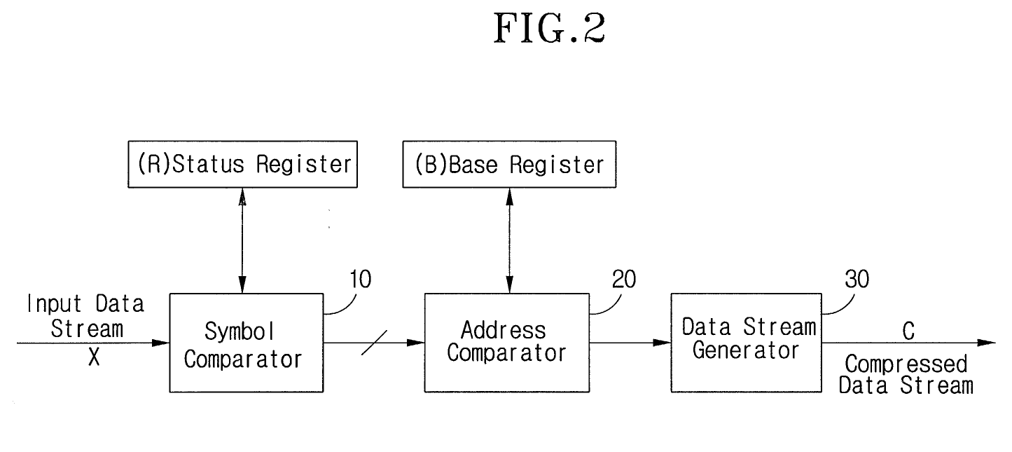

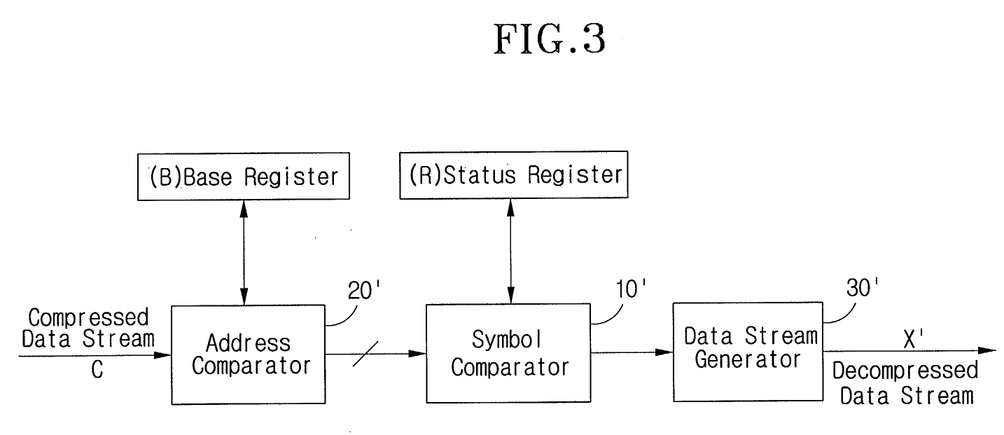

The compression method according to the present invention may be carried out by using, for example, a compressor illustrated in FIG. 2 and the decompression method in a decompressor illustrated in FIG. 3.

Referring to FIG. 2, the compressor includes a symbol comparator 10, an address comparator 20, and a data stream generator 30. A status register R and a base register B are coupled to the symbol comparator 10 and the address comparator 20, respectively. The symbol comparator 10 detects a symbol having the same value as that stored in the status register R, among unit symbol of the input data stream X. The address comparator 20 produces a location value (address) of the base register B, which is corresponding to the detected symbol from the symbol comparator 10. The data stream generator 30 compresses the output data stream C by using a compression algorithm according to this invention.

Next, referring to FIG. 3, the decompressor comprises an address comparator 20′, a symbol comparator 10, and a data stream generator 30′. As similar to the above compressor, a base register B and a status register R are coupled to the address comparator 20′ and the symbol comparator 10′, respectively.

The address comparator 20′ produces a location value (address) of the base register B, which is corresponding to each unit symbol of compressed incoming data stream C provided by the compressor. The symbol comparator 10′ compares the symbol location value outputted from the address comparator 20′ with that in the status register R and outputs the same symbol location value. The data stream generator 30′ also decompresses the restored data stream X′ by using a decompression algorithm of this invention.

Compression Algorithm

Assuming a uniform entropy data stream X to be compressed as the following expression.

X={X₁, X₂, X₃, . . . Xₘ} (1)

Where the bit size of symbol “Xᵢ” is “n” bits, and we may suppose two “n” bit registers like below:

Status register: R={A₁, A₂, A₃, . . . , Aₙ}

Base register: B={B₁, B₂, B₃, . . . , Bₙ}

Registers R and B are a register having the symbol of n pieces and it is supposed that each symbol has different value and values of the two registers are the same before initiation of the encoding operation. The value of the status register R is changed by the contents of input data stream X, but the value of the base register B has no change. The output of data stream using the declared status register can be written as follows.

C={C₁, C₂, C₃, . . . , Cₘ} (2)

The following is a description of encoding process in sequential order.

Step 1. The first symbol value X₁ of data stream X is inputted to the first symbol C₁ of data stream C, and then the symbol Aᵢ of status register R having the same value as X₁ moves to the position of Aₙ₊₁. Here, the symbol array of status register R is written as follows:

R={A₁, A₂, A₃, . . . , Aᵢ₋₁, Aᵢ₊₁, . . . , Aₙ₋₁, Aₙ, Aᵢ} (3)

Step 2. After searching the symbol value of status register R having the same value as that of the second input symbol X₂, the value of base register B corresponding to the symbol value is stored to C₂. For example, C₂ will have value B₃ of the base register B which is corresponding to the position of A₃ in case that the value of X₂ is identical with A₃. Here, the symbol array of status register R can be written as follows:

R={A₁, A₂, A₄, . . . , Aᵢ₋₁, Aᵢ₊₁, . . . , Aₙ₋₁, Aₙ, Aᵢ, A₃} (4)

Step 3. Repetitively perform the operation of Step 2 by Xₘ for each symbol of input data stream X, and then stores obtained symbol value to the data stream C.

Step 4. Compress the data stream C of non-uniform entropy property, by using conventional compression algorithms such as Huffman, Arithmetic and Lempel-Ziv.

Decompression Algorithm

Data stream C, which is the output of compression process, is used as input data for decompression operation and is processed by using the status register R and the base register B. Register R and B are initialized to the same value as those used in the compression process.

The following is a description of decompression process in sequential order.

Step 1. Extracts the data stream C from the compressed data stream with the same method used in the compression step 4.

Step 2. The first symbol value C₁ of data stream C is inputted to the first symbol X₁ of data stream X, and then move the symbol Aᵢ of status register R having the same value as C₁ to the position of Aₙ₊₁. Here, the symbol array of status register R can be written as follows:

R={A₁, A₂, A₃, . . . , Aᵢ₋₁, Aᵢ₊₁, . . . , Aₙ₋₁, Aₙ, Aᵢ}

Step 3. Searching the symbol value of the base register B that has the same value as the second input symbol C₂, and storing the value of the status register R corresponding to the symbol value onto X₂. For example, X₂ will have the value A₃ of the status register R which is corresponding to the position of B₃, in case that the value of C₂ is identical with that of B₃. Here, the symbol array of the status register R can be written as follows:

R={A₁, A₂, A₄, . . . , Aᵢ₋₁, Aᵢ₊₁, . . . , Aₙ₋₁, Aₙ, Aᵢ, A₃}

Step 4. Repetitively perform the operation of Step 2 by Cₘ for each symbol of input data stream C and then stores to the data stream X to complete decompression process.

For the simplicity of description, it is supposed that occurring symbols in a data stream are four characters (2 bits code), and the algorithm of this invention is applied to uniform entropy data stream S′ having the same occurrence probability of P=0.25, as mentioned in the foregoing description. The uniform entropy data stream S′ may be expressed as follows:

S′=X={a, d, c, b, d, a, b, c, a, c, d, b, c, d, b, a}

Because S′ is the data stream as an input, it is identical with the data stream X described above.

The compression and decompression cycle using the data stream X as an input are shown in the following Table 3 and Table 4.

TABLE 3
Compression Cycle
B = {a, b, c, d}

| Cycle | X (S′) | R-1 | R | C |
|---|---|---|---|---|
| 0 | a | {a, b, c, d} | {b, c, d, a} | a |
| 1 | d | {b, c, d, a} | {b, c, a, d} | c |
| 2 | c | {b, c, a, d} | {b, a, d, c} | b |
| 3 | b | {b, a, d, c} | {a, d, c, b} | a |
| 4 | d | {a, d, c, b} | {a, c, b, d} | b |
| 5 | a | {a, c, b, d} | {c, b, d, a} | a |
| 6 | b | {c, b, d, a} | {c, d, a, b} | b |
| 7 | c | {c, d, a, b} | {d, a, b, c} | a |
| 8 | a | {d, a, b, c} | {d, b, c, a} | b |
| 9 | c | {d, b, c, a} | {d, b, a, c} | c |
| 10 | d | {d, b, a, c} | {b, a, c, d} | a |
| 11 | b | {b, a, c, d} | {a, c, d, b} | a |
| 12 | c | {a, c, d, b} | {a, d, b, c} | b |
| 13 | d | {a, d, b, c} | {a, b, c, d} | b |
| 14 | b | {a, b, c, d} | {a, c, d, b} | b |
| 15 | a | {a, c, d, b} | {c, d, b, a} | a |

TABLE 4
Decompression Cycle
B = {a, b, c, d}

| Cycle | C | R-1 | R | X′ |
|---|---|---|---|---|
| 0 | a | {a, b, c, d} | {b, c, d, a} | A |
| 1 | c | {b, c, d, a} | {b, c, a, d} | D |
| 2 | b | {b, c, a, d} | {b, a, d, c} | C |
| 3 | a | {b, a, d, c} | {a, d, c, b} | B |
| 4 | b | {a, d, c, b} | {a, c, b, d} | D |
| 5 | a | {a, c, b, d} | {c, b, d, a} | A |
| 6 | b | {c, b, d, a} | {c, d, a, b} | B |
| 7 | a | {c, d, a, b} | {d, a, b, c} | C |
| 8 | b | {d, a, b, c} | {d, b, c, a} | A |
| 9 | c | {d, b, c, a} | {d, b, a, c} | C |
| 10 | a | {d, b, a, c} | {b, a, c, d} | D |
| 11 | a | {b, a, c, d} | {a, c, d, b} | B |
| 12 | b | {a, c, d, b} | {a, d, b, c} | C |
| 13 | b | {a, d, b, c} | {a, b, c, d} | D |
| 14 | b | {a, b, c, d} | {a, c, d, b} | B |
| 15 | a | {a, c, d, b} | {c, d, b, a} | A |

As can be seen from the Table 3, uniform entropy data stream X, which could be compressed by conventional compression method, is encoded into the form of non-uniform entropy data which can be compressed. The property of data entropy per symbol between the input data stream X and the encoded data stream C can be found in Table 5.

TABLE 5
Comparison of Data Entropy (Probability) Per Symbol

| Symbol | Data Stream X | Data Stream C |
|---|---|---|
| a | 0.25 | 0.4375 |
| b | 0.25 | 0.4375 |
| c | 0.25 | 0.125 |
| d | 0.25 | 0 |
| Property | Uniform Entropy | Non-Uniform Entropy |
| | (Uncompressible) | (Compressible) |

As apparent from the Table 4, the data stream X′ which has been decompressed by the method of this invention has the identical data value with that of the original input data stream X, demonstrating perfect lossless compression/decompression operation.

Particularly, the lossless compression method of this invention provides for additional compression for the compressed data by conventional lossy compression method. Furthermore, an effective compression for input data stream mixed with uniform and non-uniform entropy data property can be accomplished. Also, it is possible to compress random data input which is not identified of its property.

In the present invention, data storage efficiency is enhanced by the compression of lossy/lossless data in a memory device such as SRAM, DRAM and Flash ROM as well as in recording medium such as HDD, DVD and CD-RW. Also, reducing bandwidth of data transmission in digital broadcasting and mobile telephone is possible.

Although the invention has been particularly shown and described with reference to a preferred embodiment thereof, it will be understood by those skilled in the art that changes and modification in detail may be made therein without departing from the spirit and scope of the invention.

1. A method for compressing data stream of uniform entropy data in which incoming unit character has the same occurrence frequency, the method including the step of converting the uniform entropy property of data stream at temporal period into non-uniform entropy property using correlation of continuous binary code combination and random occurrence thereof in the incoming data stream, thereby compressing the uniform entropy data in a lossless way.

2. A method for compressing data stream of uniform entropy data by modulating incoming data stream by slicing unit symbol thereof to have orthogonal correlation characteristics, the method comprising the steps of:
inputting a first symbol value X₁ of the incoming data stream X to a first symbol C₁ of output data stream C and moving the symbol Aᵢ of a status register having the same value as X₁ to the position Aₙ₊₁ thereof;
searching the symbol value of the status register having the same value as that of the second input symbol X₂ and storing the value of a base register corresponding to the obtained symbol value to C₂ of the output data stream C;
performing repetitively the step of searching and storing the symbol value by Xₘ for each symbol of the input data stream X, and then storing obtained symbol value to the output data stream C; and
compressing the output data stream C by using conventional compression algorithms;
wherein the status register and the base register both have n symbols having different value each other and values of the two registers are the same before initiation of the encoding operation; and
wherein the value of the status register is changed by the contents of input data stream X, but the value of the base register remains unchanged.

3. A method for decompressing the data stream compressed according to claim 2 by using the status register and the base register, the method comprising the steps of:
extracting data stream C from the compressed data stream with the same method used in the compression step of claim 2;
inputting the first symbol value C₁ of the data stream C to the first symbol X₁ of data stream X, and moving the symbol Aᵢ of status register having the same value as C₁ to the position Aₙ₊₁ of the status register;
searching the symbol value of the base register that has the same value as the second input symbol C₂ of the data stream C, and storing the value of the status register corresponding to the symbol value onto X₂; and
performing repetitively the above step 2 operation by Cₘ for each symbol of input data stream C and storing them to the data stream X.

4. The method in accordance with claim 3, wherein the status register and base register are initialized to the same value as those used in the compression process of claim 2.
